(19) United States
(12) Patent Application Publication
(10) Pub. No.: US 2011/0266147 A1
(43) Pub. Date: Nov. 3, 2011

(54) SPUTTERING DEVICE WITH ROTATABLE TARGETS

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/857,571

(22) Filed: Aug. 17, 2010

(30) Foreign Application Priority Data
Apr. 29, 2010 (TW) 99113604

(51) Int. Cl. C23C 14/34

(52) U.S. Cl. 204/298.28

(57) ABSTRACT

A sputtering apparatus includes a housing having an enclosure and a plurality of gas-introduction holes defined in the sidewalls of the enclosure, a substrate holder for holding substrates, a plurality of targets surrounding the substrate holder, the targets and the substrate holder are accommodated in the housing, and a driving member for rotating the targets such that the targets can be selectively oriented to face the substrate holder or the gas-introduction holes.

### BACKGROUND

1. Technical Field

The present disclosure relates to sputtering technology, and particularly, to a sputtering apparatus having rotatable targets.

2. Description of Related Art

Sputtering is a physical vapor deposition process, where atoms in a solid target are ejected into the gas phase, a reaction occurs between the atoms and the gas phase, and then a layer is deposited on workpieces facing the target.

However, during a reactive sputtering process, unwanted products are simultaneously produced in the reaction, such as oxide, nitride, etc, and often adhere on the target. As a result, the sputtering process has to be interrupted for cleaning the target. This reduces production and deposition efficiency. Therefore, it is desired to provide a sputtering device capable of simultaneously cleaning the target and forming layers to improve production and deposition efficiency.

### BRIEF DESCRIPTION OF THE DRAWINGS

Many aspects of the present sputtering apparatus can be better understood with reference to the following drawings. The components in the drawings are not necessarily drawn to scale, the emphasis instead being placed upon clearly illustrating the principles of the present sputtering apparatus. Moreover, in the drawings, like reference numerals designate corresponding parts throughout the several views.

FIG. 1 is an isometric and exploded view of a sputtering apparatus in accordance with a first embodiment, the sputtering apparatus includes a substrate holder.

FIG. 2 is an isometric view of the substrate holder of FIG. 1.

FIG. 3 is an isometric and exploded view of another sputtering apparatus in accordance with a second embodiment.

### DETAILED DESCRIPTION

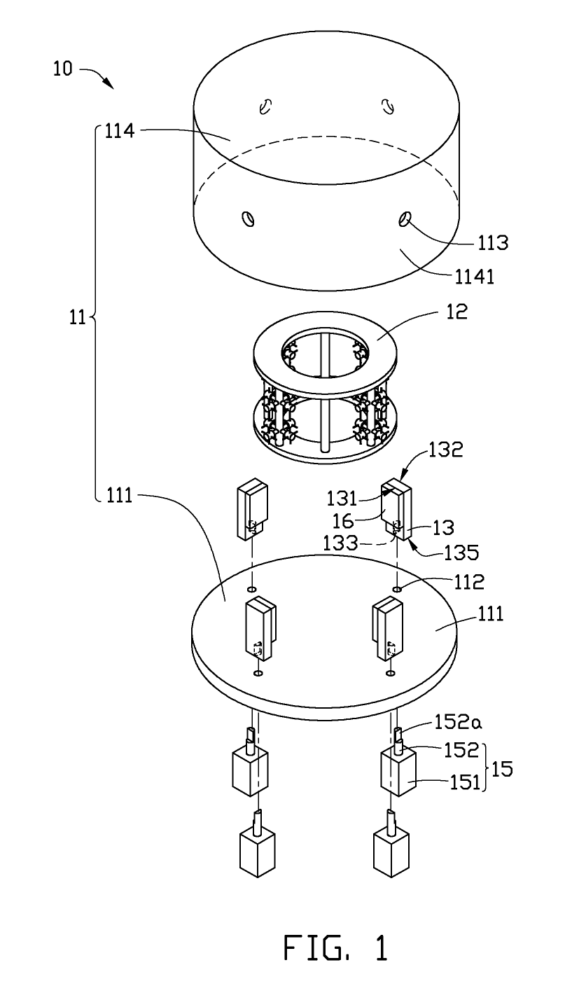

Referring to FIG. 1, a sputtering apparatus 10 provided in a first embodiment encompasses a housing 11, a substrate holding device 12, four target holders 13, four targets 16, and four driving members 15.

The housing 11 is cylindrical, and includes an enclosure 114 and a supporting plate 111 coupled with the enclosure 114. Four gas-introduction holes 113 are equidistantly arranged in a sidewall 1141 of the enclosure 114. The enclosure 114 and the supporting plate 111 are configured for cooperatively accommodating the substrate holder 12, the target holder 13 and the targets 16.

The substrate holder 12 is coaxially mounted on the supporting plate 111.

The supporting plate 111 defines four positioning holes 112 surrounding the substrate holder 12. The substrate holder 12 includes an top annular panel 121, a bottom annular panel 122, a plurality of spindles 123 rotatably interconnecting the top panel 121 and the bottom panel 122, a plurality of cylinder rods 124, and a plurality of holding members 125. Each spindle 123 is rotatable around its central axis. Each rod 124 radially extends from the spindles 123. The four holding members 125 radially extend from the rod 124, and are used for holding a substrate to be sputtered.

Each target holder 13 has a first surface 131, a second surface 132 opposite to the first surface 131, and a bottom surface 135 interconnecting the first surface 131 and the second surface 132. In addition, each target holder 13 defines an engaging recess 133 in the bottom surface 135. Each target 16 is fixed on the first surface 131 of each of the target holders 12, and adjacent to a corresponding gas-introduction hole 113.

Each driving member 15 includes an actuator 151, a rotatable shaft 152 and a fastening element 152a. The actuator 151 is configured for driving the rotatable shaft 152 around its central axis. The central axis of the rotatable shaft 152 is parallel to the central axis of the cylindrical enclosure 114. The fastening element 152a extends from an end of the rotatable shaft 152 up, passes through a corresponding positioning hole 112, and then engages in the engaging recess 135 of the target holder 135. In this manner, the target holder 13 is rotatable about an axes parallel to the central axis of the enclosure 114 when the rotatable shaft 152 is rotated, and the target 16 on each target holder 13 is selectively oriented to face the substrate holder 12 and a corresponding gas-introduction hole 113.

In actual sputtering process, take cleaning one target 14 for instance, the target 14 to be cleaned is rotated by the actuator 151 till facing a corresponding gas-introduction hole 113. An inert gas is introduced into the housing 11 through the corresponding gas-introduction hole 113 to bombard the target 14 such that contaminant on the target 14 can be removed. Meanwhile, the residual targets 14 face the substrate holder 12. A reactive gas is introduced into the housing 11 through residual gas-introduction holes 113 for reaction with the residual targets 14 such that a layer can be formed on workpieces on the substrate holder 12. That means, the target 14 can be cleaned without interrupting sputtering. Therefore, production and deposition efficiency are improved.

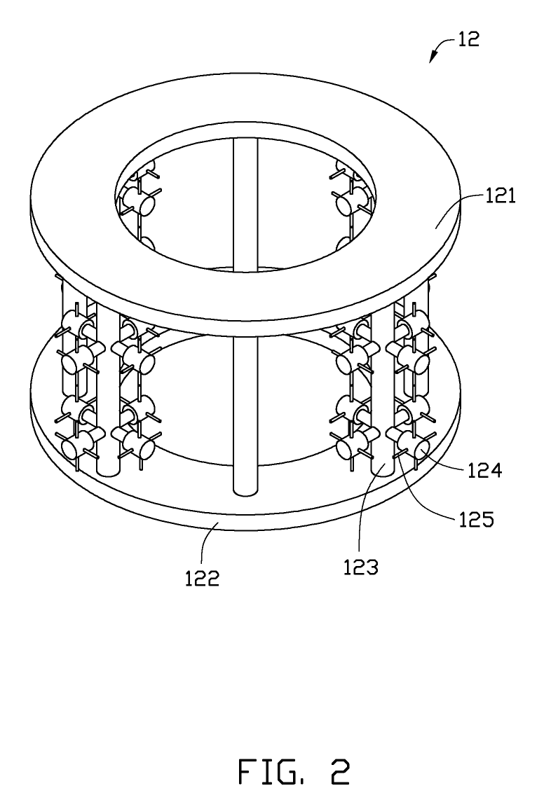

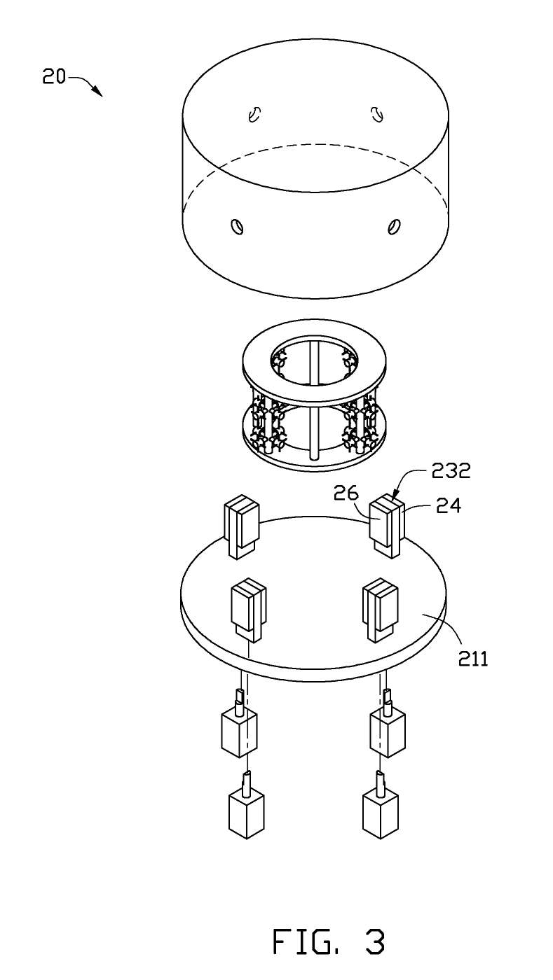

Referring to FIGS. 2 and 3, another sputtering apparatus 20 has similar configuration with that of the sputtering apparatus 10, except it includes four magnetic elements 24 each respectively mounted on the second surface 232 of each target holder 23. That is, a target 26 and a magnetic element 24 are respectively mounted on two opposite surfaces of the target holder 23. The magnetic elements 24 are used for speeding gas ionization such that bump rate between the target 26 and the gas is increased. Preferably, projections of the four magnetic elements 24 to the supporting plate 211 are on an imaginary circle.

The above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A sputtering apparatus, comprising:
a housing having an enclosure and a plurality of gas-introduction holes defined in sidewalls of the enclosure;
a substrate holder for holding substrates;
a plurality of targets surrounding the substrate holder, the targets and the substrate holder being accommodated in the housing; and
a driving member for rotating the targets such that the targets can be selectively oriented to face the substrate holder or the gas-introduction holes.

2. The sputtering apparatus of claim 1, wherein the housing further comprises a supporting plate, the supporting plate and the enclosure cooperatively accommodating the targets and the substrate holders, the substrate holder mounted on the supporting plate.

3. The sputtering apparatus of claim 2, further comprising a plurality of target holders, wherein the targets are fixed on the corresponding target holders, the driving members pass through the supporting plate and engage with the respective target holders.

4. The sputtering apparatus of claim 3, further comprising a plurality of magnetic members, each of magnetic members is fixed on an opposite surface of the respective target holder to the corresponding target.

5. The sputtering apparatus of claim 2, wherein the substrate holder comprises a top annular plate, a bottom annular plate, a plurality of spindles rotatably interconnecting with the top and the bottom plates, a plurality of rods radially extend from each spindle, and a plurality of holding members radially extend from each rod.

6. A sputtering apparatus, comprising:
a housing having an cylindrical enclosure and a plurality of gas-introduction holes defined in a sidewall of the cylindrical enclosure, the cylindrical enclosure having a central axis;
a substrate holder for holding substrates;
a plurality of targets surrounding the substrate holder spatially corresponding to the gas-introduction holes, the targets and the substrate holder being accommodated in the housing; and
a driving member for rotating each of the targets about axes parallel to the central axis such that each the targets can be selectively oriented to face the substrate holder or the gas-introduction holes.
